(19) United States
(12) Patent Application Publication
(10) Pub. No.: US 2013/0112965 A1
(43) Pub. Date: May 9, 2013

(54) ORGANIC LIGHT-EMITTING DEVICE MATERIAL HAVING DIBENZOSUBERONE SKELETON

(71) Applicants: Takeshi Sekiguchi, Tokyo (JP); Akihito Saitoh, Gotemba-shi (JP); Jun Kamatani, Tokyo (JP); Hirokazu Miyashita, Tokyo (JP)

(72) Inventors: Takeshi Sekiguchi, Tokyo (JP); Akihito Saitoh, Gotemba-shi (JP); Jun Kamatani, Tokyo (JP); Hirokazu Miyashita, Tokyo (JP)

(73) Assignee: CANON KABUSHIKI KAISHA, Tokyo (JP)

(21) Appl. No.: 13/809,846

(22) PCT Filed: Jul. 8, 2011
(86) PCT No.: PCT/JP2011/066171

§ 371 Date: Jan. 11, 2013

(30) Foreign Application Priority Data
Jul. 14, 2010 (JP) 2010-159625

(51) Int. Cl. H01L 51/00

(52) U.S. Cl. 257/40; 568/326; 549/43

(57) ABSTRACT

The present invention provides an organic light-emitting device material that exhibits high emission efficiency and is used in an organic light-emitting device having a low driving voltage. The organic light-emitting device material is represented by general formula (1) below:

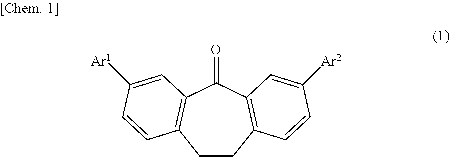

### TECHNICAL FIELD

The present invention relates to materials for organic light-emitting devices and organic light-emitting devices including the materials. In particular, it relates to a dibenzosuberone compound having a specific novel seven-membered-ring structure.

### BACKGROUND ART

A light-emitting device is a device that includes an anode, a cathode, and an organic compound layer interposed between the electrodes. Holes and electrons injected from the respective electrodes of the organic light-emitting device are recombined in the organic compound layer to generate excitons and light is emitted as the excitons return to their ground state. Recent years have seen remarkable advances in the field of organic light-emitting devices. Organic light-emitting devices offer low driving voltage, various emission wavelengths, rapid response, and small thickness and are light-weight.

Phosphorescent organic light-emitting devices are a type of organic light-emitting devices that include an emission layer containing a phosphorescent material, with triplet excitons contributing to emission. In general, Alg₃ and BAlg are used as the electron transport material for phosphorescence. There is still room for further improving the emission efficiency of a phosphorescent organic light-emitting device.

PTL 1 discloses a compound containing a seven-membered-ring structure. Examples of the compounds having this seven-membered-ring structure are given below. These compounds are referred to as Compounds 1, 5, 17, and 53, respectively, in PTL 1.

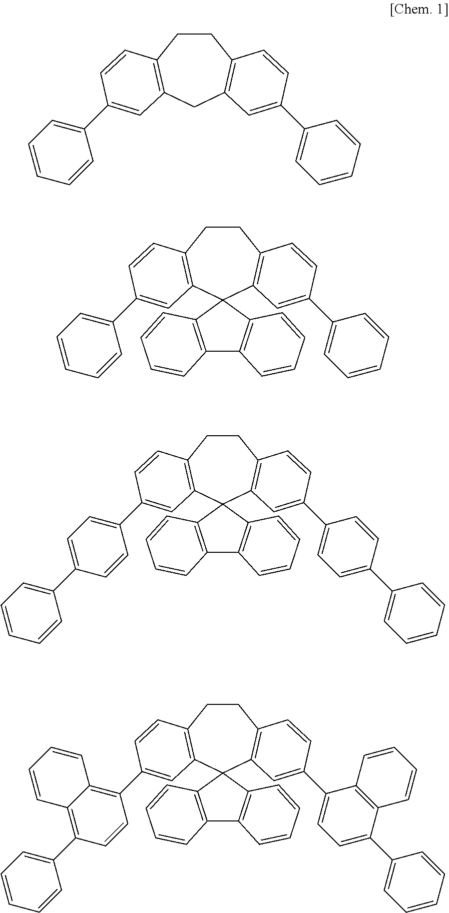

Compounds containing the seven-membered-ring structure are used as fluorescent materials or host materials for phosphorescence.

PTL 2 and NPL 1 disclose preparation of dibenzosuberenone derivatives used as starting materials for making pharmacologically active compounds in the pharmaceutical industry and describe dibenzosuberones for obtaining dibenzosuberenone derivatives.

Compounds disclosed in PTL 1 are described to be fluorescent materials or host materials. PTL 1 fails to focus on and use the electron transport property of the compounds. PTL 1 does not pay attention to the carbonyl group in the skeleton.

In developing the organic light-emitting device, the electron transport materials are desirably improved.

A chemically stable material having a deep LUMO level is desired as the electron transport material.

### CITATION LIST

### Patent Literature

PTL 1 Japanese Patent Laid-Open No. 2010-024149
PTL 2 PCT Japanese Translation Patent Publication No. 2003-508359

### Non Patent Literature

NPL 1 J. Org. Chem. 1994, 59, 7968-75

### SUMMARY OF INVENTION

The present invention provides an organic light-emitting device material having high electron transport property.

The present invention provides an organic light-emitting device material represented by general formula (1) below.

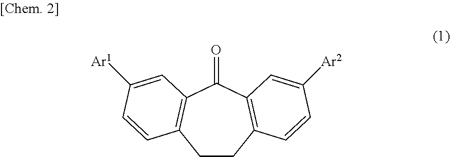

In general formula (1), Ar¹ and Ar² each independently denote a substituent selected from a phenyl group, a biphenyl group, a terphenyl group, a naphthyl group, a phenanthrenyl group, a fluorenyl group, a triphenylenyl group, and a chrysenyl group. The substituent may include at least one of an alkyl group, an aromatic hydrocarbon group, and an aromatic heterocyclic group.

The present invention provides an organic light-emitting device having a deep LUMO level of −3.0 eV or less and high T₁ energy of 2.3 eV or more. The present invention also provides an organic light-emitting device that contains this material and has high emission efficiency and low driving voltage.

### BRIEF DESCRIPTION OF DRAWINGS

FIG. 1 is a schematic cross-sectional view showing an organic light-emitting device and a switching device connected to the organic light-emitting device.

### DESCRIPTION OF EMBODIMENTS

An organic light-emitting device material according to an embodiment of the present invention is represented by general formula (1) below.

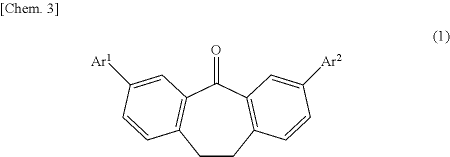

In general formula (1), Ar¹ and Ar² each independently denote a substituent selected from a phenyl group, a biphenyl group, a terphenyl group, a naphthyl group, a phenanthrenyl group, a fluorenyl group, a triphenylenyl group, and a chrysenyl group. The substituent may include at least one of an alkyl group, an aromatic hydrocarbon group, and an aromatic heterocyclic group.

The substituent, i.e., a phenyl group, a biphenyl group, a terphenyl group, a naphthyl group, a phenanthrenyl group, a fluorenyl group, a triphenylenyl group, or a chrysenyl group, may have a substituent.

Examples of the substituent include alkyl groups such as a methyl group, an ethyl group, an n-propyl group, an iso-propyl group, an n-butyl group, an iso-butyl group, a sec-butyl group, and a tert-butyl group, aromatic hydrocarbon groups such as a phenyl group, a naphthyl group, a phenanthryl group, and a fluorenyl group, and aromatic heterocyclic groups such as a thienyl group, a dibenzofuran group, a dibenzothiophene group, a pyrrolyl group, and a pyridyl group.

The organic light-emitting device material exhibits high electron transport property, film-forming property, and chemical stability and has high T₁ energy.

### Properties of Dibenzosuberone Compound

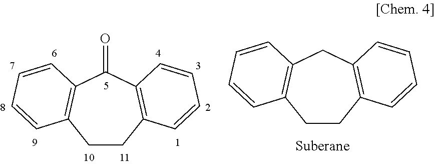

The structural formulae of the dibenzosuberone skeleton used as the organic light-emitting device material of an embodiment of the present invention and suberane are shown above. Since the carbon atoms at the 10- and 11-positions of the dibenzosuberone skeleton are aliphatic carbons, the compound does not crystallize easily and tends to form a stable thin film.

The skeleton has a carbonyl group at the 5-position. If the 5-position is substituted with hydrogen instead of a carbonyl group, i.e., if the skeleton is suberane, the LUMO level is shallow and the electron injection/transport property is low.

According to an actual molecular orbital calculation performed at the B3LYP/6-31G* level, the LUMO level of suberane is −1.0 eV, and the LUMO level of dibenzosuberone is deeper, i.e., −1.8 eV. Because of the depth of the LUMO level derived from the carbonyl group, this skeleton is suitable as an electron transport material. When this skeleton has a specific aromatic hydrocarbon group, an organic light-emitting device material that has a deeper LUMO level, i.e., −3.0 eV or less, is obtained. When the organic light-emitting device material of this embodiment is used in an emission layer or a layer adjacent to the emission layer, the driving voltage of the organic light-emitting device can be decreased. This is because a deep LUMO level lowers the electron injection barrier from the adjacent layers.

Dibenzosuberone is liquid at room temperature. In order to prevent molecules from becoming liquid at room temperature, substituents are introduced to increase the molecular weight. The molecular weight may be 360 or more. In order to increase the rigidity of the molecules, the substituents may be aromatic hydrocarbon groups. The organic light-emitting device material of this embodiment may have two aromatic hydrocarbon groups. This increases the molecular weight and raises the glass transition temperature (Tg). Aromatic hydrocarbon groups refer to aromatic ring groups constituted by carbon and hydrogen atoms only. Examples of the aromatic hydrocarbon groups include a phenyl group, a biphenyl group, a terphenyl group, a naphthyl group, a phenanthrenyl group, a fluorenyl group, a triphenylenyl group, and a chrysenyl group, as described above. These aromatic hydrocarbon groups may have any one of an alkyl group, an aromatic hydrocarbon group, and an aromatic heterocyclic group, as described above.

The two aromatic hydrocarbon groups may be located at the 3-position and the 7-position of the dibenzosuberone skeleton.

The influence of the steric hindrance is great when aromatic hydrocarbon groups are located at other positions. In particular, the influence of the steric hindrance is great when the 10- and 11-positions are substituted with aromatic hydrocarbon groups. The 10- and 11-positions may be substituted with hydrogen atoms.

The stability of the molecule is also impaired when the 1-, 4-, 6-, and 9-positions are substituted with aromatic hydrocarbon groups due to steric hindrance. These positions may also be substituted with hydrogen atoms.

In sum, the two aromatic hydrocarbon groups may be located at the 3- and 7-positions or the 2- and 8-positions. Preferably, the organic light-emitting device material of this embodiment includes aromatic hydrocarbon groups at the 3- and 7-positions. This is because when aromatic hydrocarbon groups are introduced to the 3- and 7-positions, the T₁ energy of the dibenzosuberone compound is increased. Thus, a phosphorescent material may be used as the emission material. According to this organic light-emitting device, the organic light-emitting device material of this embodiment may be used in one or both of an emission layer and an organic compound layer different from the emission layer but adjacent to the emission layer. This organic compound layer is an electron transport layer. An electron transport layer is a layer in contact with the cathode-side of the emission layer. It is not necessary that the organic light-emitting device include the additional organic compound layer. In such a case, the organic light-emitting device material according to an embodiment of the invention is contained in the emission layer.

When the emission color of the phosphorescent material is blue to red, i.e., the maximum peak in the emission wavelength spectrum is 440 nm to 620 nm, it is important that the T₁ energy of the dibenzosuberone compound be determined according to the emission color of the phosphorescent material. In particular, a dibenzosuberone compound that has a T₁ energy that can be converted into a wavelength shorter than the wavelength of the maximum peak of the emission wavelength spectrum of the phosphorescent material is selected. In making this selection, substituents to be introduced to the 3- and 7-positions of the dibenzosuberone skeleton are selected.

The T₁ energy (on a wavelength basis) of benzene and major fused rings which are favorable substituents to be introduced into the 3- and 7-positions of the dibenzosuberone skeleton is shown in Table 1.

TABLE 1

| | | T₁ energy |
|---|---|---|
| | | on a |
| | Structural | wavelength |
| Name | formulae | basis |
| Benzene | 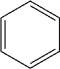 | 339 nm |
| Naphthalene | 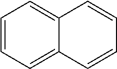 | 472 nm |
| Fluorene | 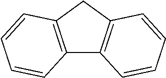 [SMILES: c1ccc2c(c1)Cc1ccccc1-2] | 422 nm |
| Phenanthrene | 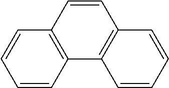 [SMILES: c1ccc2c(c1)ccc1ccccc12] | 459 nm |
| Triphenylene | 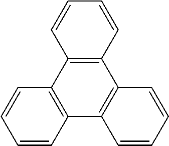 [SMILES: c1ccc2c(c1)c1ccccc1c1ccccc21] | 427 nm |
| Pyrene | 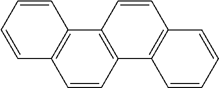 [SMILES: c1ccc2c(c1)ccc1c3ccccc3ccc21] | 500 nm |

When the emission color of the phosphorescent material is blue to green, benzene, phenanthrene, fluorene, and triphenylene are preferred among these. “Blue to green” refers to the range of 440 nm to 530 nm.

Since the carbon atoms at the 10- and 11-positions of the dibenzosuberone skeleton are aliphatic carbon atoms, the conjugated system does not expand and high T₁ energy is achieved. Thus the dibenzosuberone skeleton has significantly high T₁ energy, i.e., 431 nm on a wavelength basis. The substituents presented in Table 1 do not significantly decrease the T₁ energy of the dibenzosuberone and thus high T₁ is maintained.

Since the 2- and 8-positions of the dibenzosuberone skeleton are para positions with respect to the carbonyl group, the T₁ energy will decrease if the 2- and 8-positions are substituted with aromatic hydrocarbon groups.

Ar¹ and Ar² in general formula (1) are preferably the same group since such a compound is easy to synthesize. The organic light-emitting device material according to the invention may have Ar¹ and Ar² the same or different from each other.

In sum, the organic light-emitting device material of this embodiment has high electron transport property, film-forming property, chemical stability, and T₁ energy.

### Organic Light-Emitting Device

An emission layer of the organic light-emitting device may contain two or more components.

Two or more components may be an emission material (guest material) and a material other than the emission material. The material other than the emission material may be a host material. A material other than the emission material and the host material may also be contained in the emission layer. This material is called an assisting material or a second host material. The organic light-emitting device material of the invention may be contained in the emission layer but not as the emission material. To be more specific, the organic light-emitting device material may be contained as a host material, an assisting material, or a second host material but is preferably contained as a host material.

A host material is a compound that serves as a matrix that surrounds the guest material in the emission layer and is primarily responsible for transporting carriers and donating excitation energy to the guest material.

The concentration of the guest material is 0.01 to 50 wt % and preferably 0.1 to 20 wt % with respect to the total amount of the materials constituting the emission layer. The guest material may be contained in a layer composed of a host material, either homogeneously or by having a concentration gradient, or may be contained in some portions of the host material layer while leaving other portions free of the guest material.

When the organic light-emitting device material of the invention is used as an assisting material, the content thereof is 0.01 to 50 wt % and preferably 0.1 to 20 wt % with respect to the total amount of the materials constituting the emission layer.

The electron transport layer has functions of transporting and injecting electrons into the emission layer, blocking holes, and giving and receiving electrons to and from the electrodes. The electron transport layer may be constituted by a single layer or two or more layers.

Examples of the Dibenzosuberone Compounds of the invention

Specific examples of the structural formulae of the organic light-emitting device material of the invention are as follows.

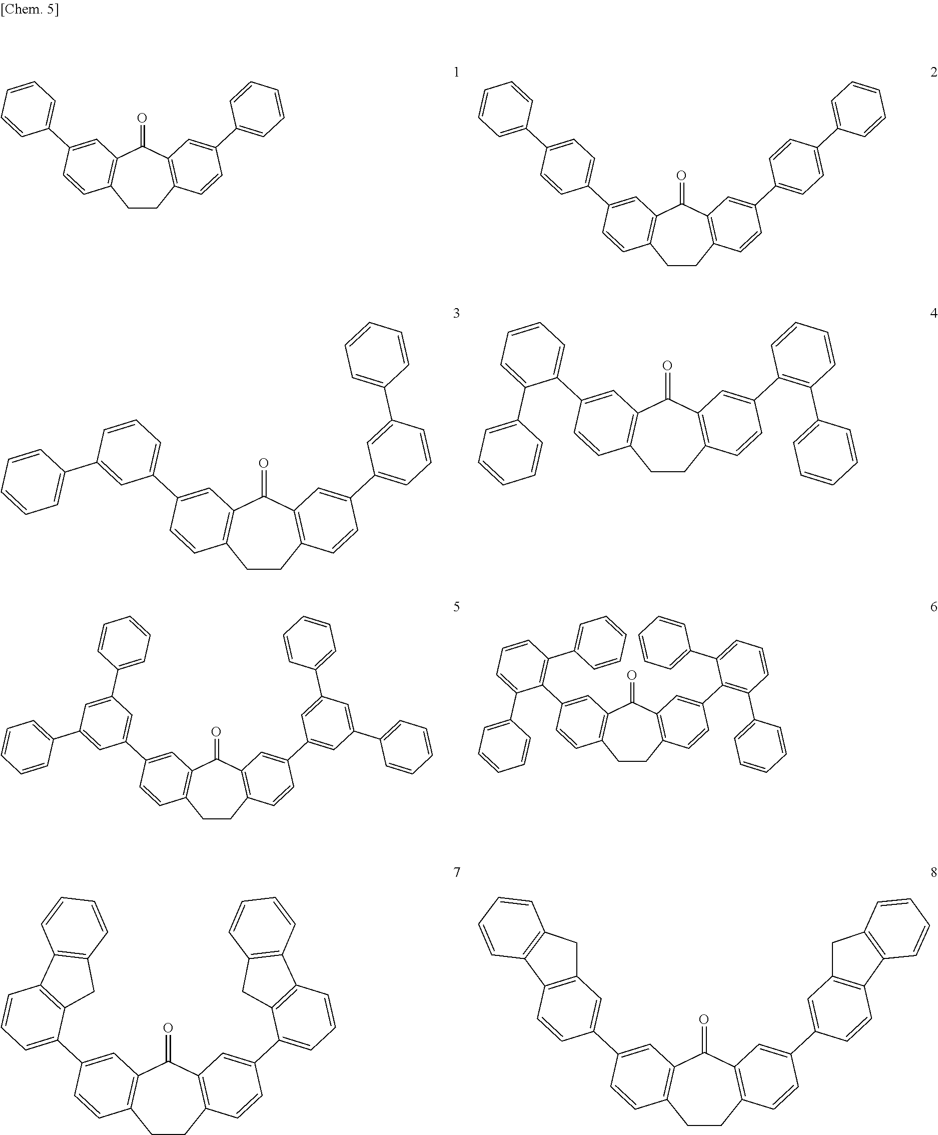

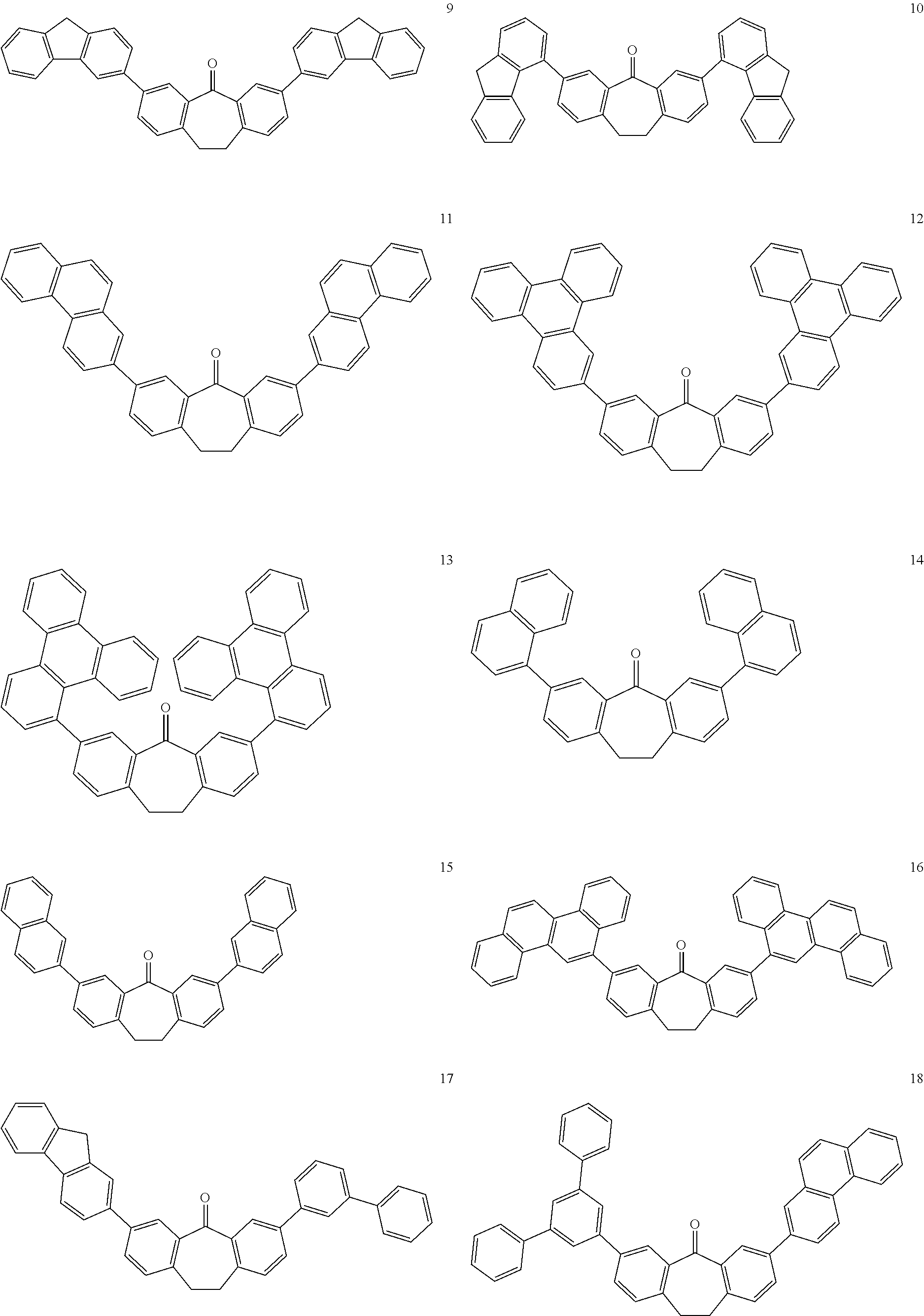

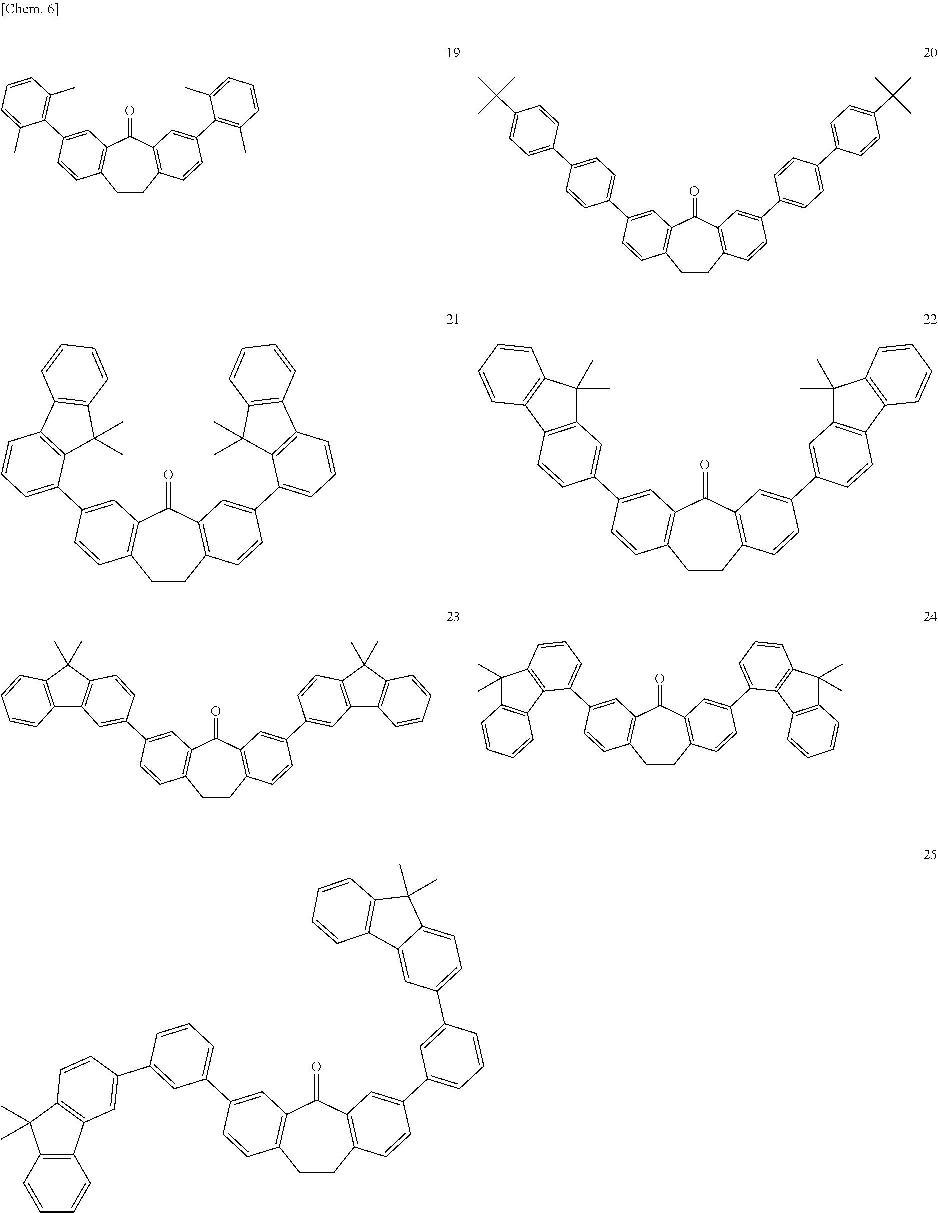

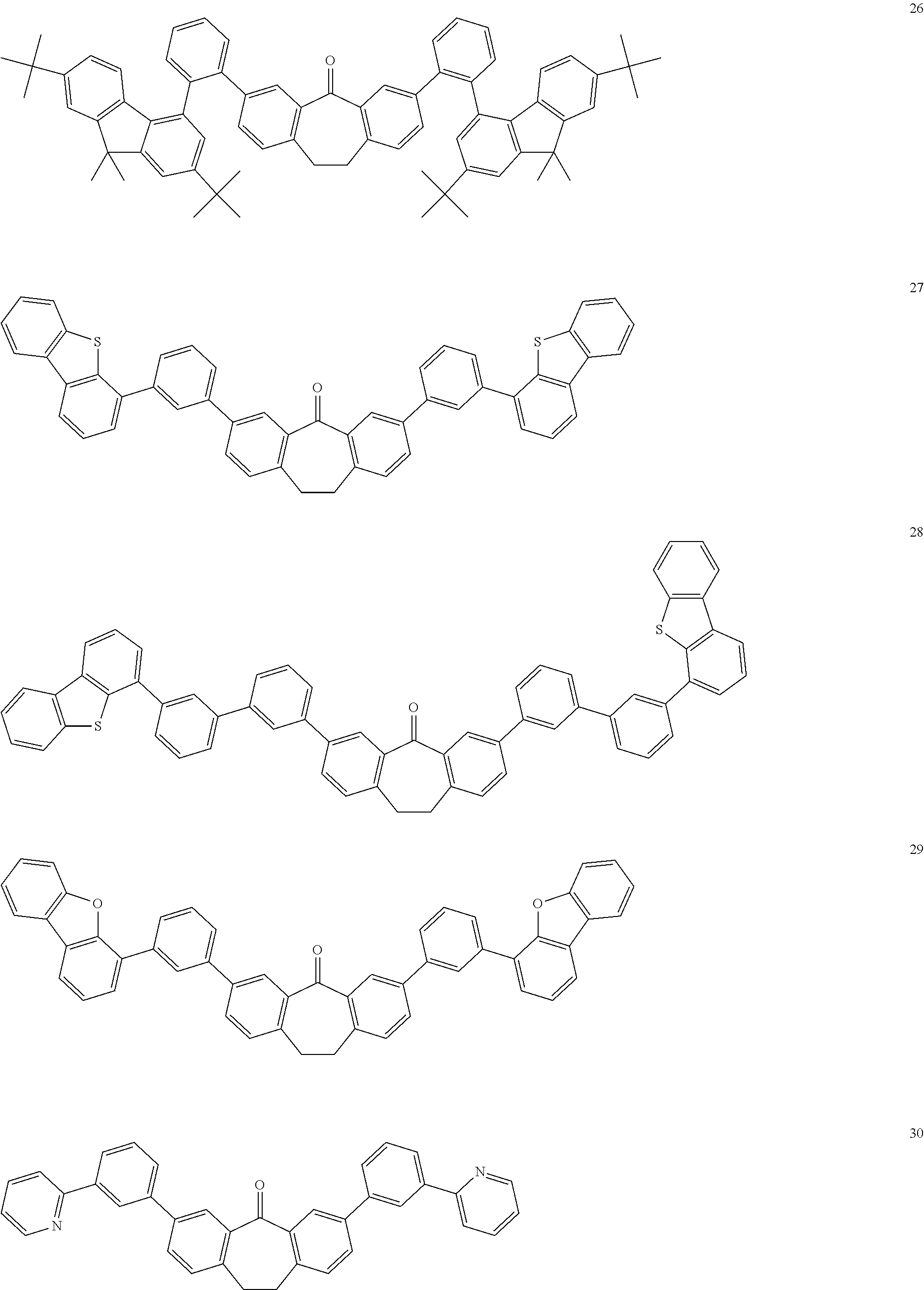

Of Example Compounds listed above, compounds 1 to 13 and 27 have T₁ energy in the range of 440 nm to 530 nm, i.e., blue to green. Thus, a blue to green organic light-emitting device that uses any of these compounds as an electron transport material or an emission layer host material can exhibit high emission efficiency.

Of Example Compounds listed above, compounds 14 to 16 have T₁ energy in the range of 530 nm to 620 nm, i.e., green to red. A green to red organic light-emitting device that uses any of these compounds as an electron transport material or an emission layer host material can exhibit high emission efficiency.

Of Example Compounds listed above, compounds 17 and 18 are asymmetric and are highly amorphous. When these compounds are used as a material of an organic light-emitting device, a homogeneous film can be formed and stable emission can be achieved.

Of Example Compounds listed above, compounds 19 to 26 contain aliphatic carbon and have high film property and solubility. Thus these materials may be used not only in vapor deposition but also in coating in making an organic light-emitting device. The carrier mobility can also be controlled by selecting aliphatic carbon.

Of Example Compounds listed above, compounds 27 to 30 contain heterocyclic rings. These compounds have stability close to the compounds having aromatic hydrocarbon groups since the hetero atoms are located inside the cyclic groups. The carrier mobility can also be controlled by selecting the heterocyclic rings.

### Process for Synthesizing a Dibenzosuberone Compound (Organic Light-Emitting Device Material of the Invention)

Next, a process for synthesizing the dibenzosuberone compound is described.

The dibenzosuberone compound can be synthesized through a coupling reaction between 3,7-dibromodibenzosuberone and boronic acid or a boronic acid ester compound of a substituent (Ar) in the presence of a catalyst, as shown in the reaction scheme (3) below.

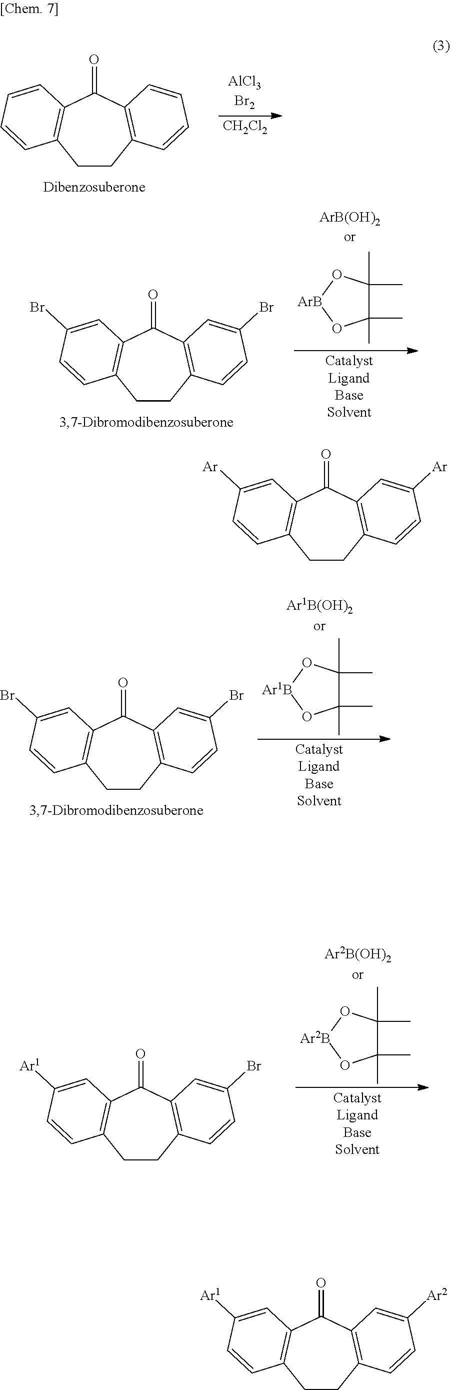

In reaction scheme (3), Ar's are each independently selected from a phenyl group, a biphenyl group, a terphenyl group, a naphthyl group, a phenanthrenyl group, a fluorenyl group, a triphenylenyl group, and a chrysenyl group. The phenyl group, the biphenyl group, the terphenyl group, the naphthyl group, the phenanthrenyl group, the fluorenyl group, and the triphenylenyl group may have a substituent. Examples of the substituent include alkyl groups such as a methyl group, an ethyl group, an n-propyl group, an iso-propyl group, an n-butyl group, an iso-butyl group, a sec-butyl group, and a tert-butyl group, aromatic hydrocarbon groups such as a phenyl group, a naphthyl group, a phenanthryl group, and a fluorenyl group, and aromatic heterocyclic groups such as a thienyl group, a dibenzofuran group, a dibenzothiophene group, a pyrrolyl group, and a pyridyl group. In the reaction scheme, each Ar is adequately selected to synthesize a desired dibenzosuberone compound. An asymmetric compound can be synthesized by allowing one equivalent of Ar¹ to react and then allowing one equivalent of Ar² different from Ar¹ to react.

The purification process for the compound of the invention performed immediately before fabrication of the organic light-emitting device may be a sublimation purification process. This is because sublimation purification has a significantly high purifying effect in increasing the purity of organic compounds. In general, sublimation purification requires high temperature as the molecular weight of the organic compound increases and thus pyrolysis tends to occur under high temperature. Accordingly, the organic compound used in the organic light-emitting device may have a molecular weight of 1000 or less so that the sublimation purification can be conducted without excessive heating.

### Organic Light-Emitting Device of the Invention

Next, an organic light-emitting device of the invention is described.

An organic light-emitting device of the invention includes an anode and a cathode that oppose each other, and at least one organic compound layer disposed between the anode and the cathode. Of the at least one organic compound layer, a layer containing an emission material is the emission layer. The organic light-emitting device of the present invention has an organic compound layer containing a dibenzosuberone compound represented by general formula (1).

Examples of the structure that can be employed in the organic light-emitting device of this embodiment includes an anode/emission layer/cathode structure, an anode/hole transport layer/electron transport layer/cathode structure, and an anode/hole transport layer/emission layer/electron transport layer/cathode structure, the layers in the structure being sequentially formed on a substrate. The emission layer may contain two or more components or may be constituted by two or more layers. Note that these three types of multilayer organic light-emitting devices are only basic device structures and the structure of the organic light-emitting device that uses the compound of the invention is not limited to these. For example, an insulating layer may be formed at the interface between an electrode and an organic compound layer, an adhesive layer or an interference layer may be provided in addition, and the electron transport layer or hole transport layer may be constituted by two layers having different ionization potentials.

The device may be of a top-emission type in which light is output from the substrate-side electrode or of a bottom-emission type in which light is output from the side remote from the substrate, or may be configured to output light from both sides.

The dibenzosuberone compound of the invention can be used in an organic compound layer of an organic light-emitting device having any layer structure. For example, the compound is preferably used in the electron transport layer or the emission layer, and more preferably used as an electron transport material 1 in the electron transport layer and a host material 2 in the emission layer.

When the dibenzosuberone compound of the invention is used as the electron transport material 1 or the host material 2 of a phosphorescent light-emitting device, the phosphorescent material used as the guest material is a metal complex such as an iridium complex, a platinum complex, a rhenium complex, a copper complex, an europium complex, or a ruthenium complex. Of these, an iridium complex having a high phosphorescent property is preferred. The emission layer may contain two or more phosphorescent materials so that transmission of excitons and carriers can be assisted.

Specific examples of the iridium complex used as the phosphorescent material and specific examples of the host material are as follows. These examples are merely illustrative and do not limit the scope of the invention.

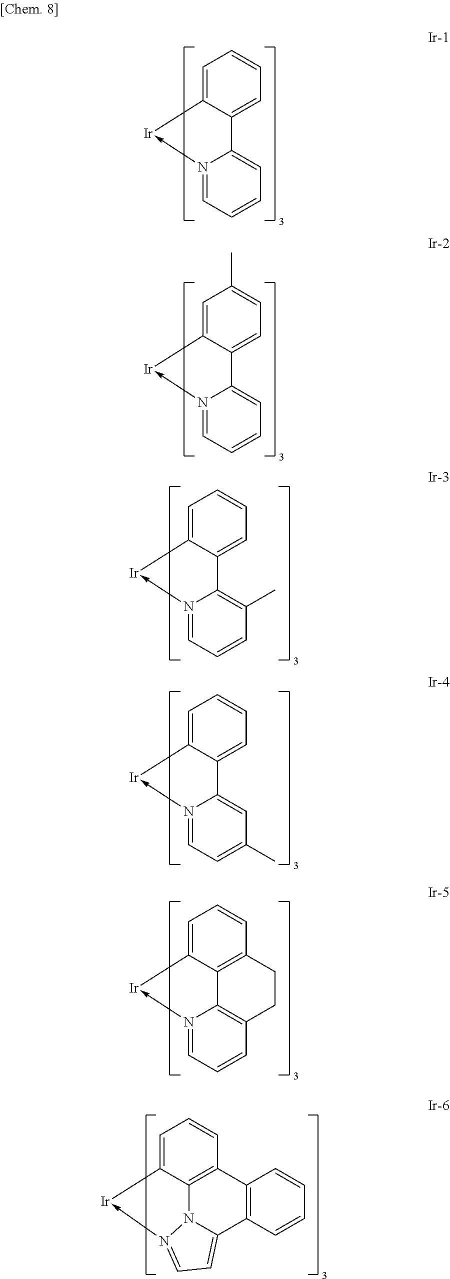

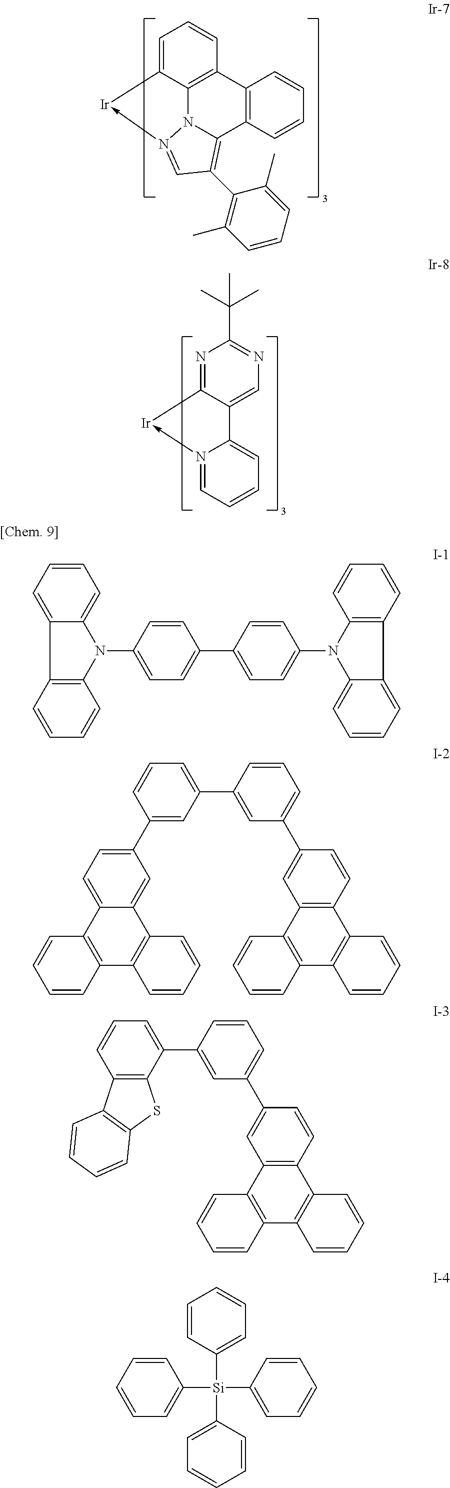

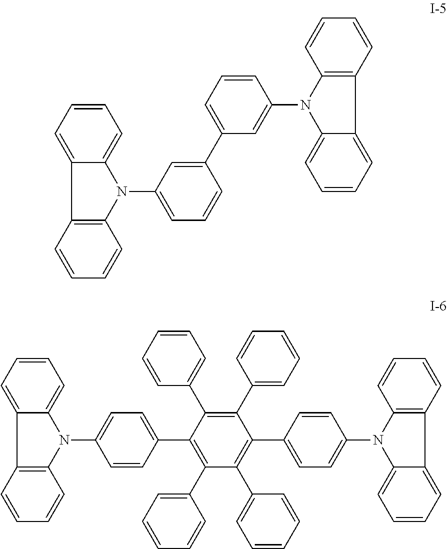 [SMILES: c1cc(-c2cccc(-n3c4ccccc4c4ccccc43)c2)cc(-n2c3ccccc3c3ccccc32)c1 ; c1ccc(-c2c(-c3ccccc3)c(-c3ccc(-n4c5ccccc5c5ccccc54)cc3)c(-c3ccccc3)c(-c3ccccc3)c2-c2ccc(-n3c4ccccc4c4ccccc43)cc2)cc1]

In addition to the compound of the present invention, other low-molecular-weight and high-molecular weight compounds of related art can be used according to need.

Examples of such compounds are as follows.

The hole transport material is preferably a material having high hole mobility so that hole can be easily injected from the anode and the injected holes can be easily transferred to the emission layer. Examples of the high-molecular-weight and low-molecular-weight compounds having hole injection/transport property include triarylamine derivatives, phenylenediamine derivatives, stilbene derivatives, phthalocyanine derivatives, porphyrin derivatives, poly(vinyl carbazole), poly(thiophene), and other conductive polymers.

Examples of the light-emitting material contributing mainly to light-emitting function include phosphorescent guest materials described above and derivatives thereof, fused ring compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, organic beryllium complexes, and polymer derivatives such as poly(phenylene vinylene) derivatives, poly(fluorene) derivatives, and poly(phenylene) derivatives.

The electron transport material can be freely selected from those materials into which electrons can be easily injected from the cathode and in which injected electrons can be transported to the emission layer. The selection is made by considering the balance with the hole mobility of the hole injection/transport material. Examples of the material having electron injection/transport property include oxadiazole derivatives, oxazole derivatives, pyrazine derivatives, triazole derivatives, triazine derivatives, quinoline derivatives, quinoxaline derivatives, phenanthroline derivatives, and organic aluminum complexes.

The anode material may have a large work function. Examples of the anode material include single metals such as gold, platinum, silver, copper, nickel, palladium, cobalt, selenium, vanadium, and tungsten or alloys thereof, and metal oxides such as tin oxide, zinc oxide, indium oxide, indium tin oxide (ITO), and indium zinc oxide. Conductive polymers such as polyaniline, polypyrrole, and polythiophene may also be used. These anode materials may be used alone or in combination. The anode may be constituted by one layer or two or more layers.

In contrast, the cathode material may have a small work function. Examples of the cathode material include alkali metals such as lithium, alkaline earth metals such as calcium, and single metals such as aluminum, titanium, manganese, silver, lead, and chromium. The single metals may be combined and used as alloys. For example, magnesium-silver, aluminum-lithium, and aluminum-magnesium alloys and the like can be used. Metal oxides such as indium tin oxide (ITO) can also be used. These cathode materials may be used alone or in combination. The cathode may be constituted by one layer or two or more layers.

A layer containing the organic compound of the embodiment and a layer composed of other organic compound of the organic light-emitting device of the embodiment are prepared by the methods below. Typically, thin films are formed by vacuum vapor deposition, ionization deposition, sputtering, plasma, and coating using an adequate solvent (spin-coating, dipping, casting, a Langmuir Blodgett method, and an ink jet method). When layers are formed by vacuum vapor deposition or a solution coating method, crystallization is suppressed and stability over time can be improved. When a coating method is employed, an adequate binder resin may be additionally used to form a film.

Examples of the binder resin include, but are not limited to, polyvinylcarbazole resins, polycarbonate resins, polyester resins, ABS resins, acrylic resins, polyimide resins, phenolic resins, epoxy resins, silicone resins, and urea resins. These binder resins may be used alone as a homopolymer or in combination of two or more as a copolymer. If needed, known additives such as a plasticizer, an antioxidant, and an ultraviolet absorber may be used in combination.

### Usage of Organic Light-Emitting Device

The organic light-emitting device of the embodiment may be used in a display apparatus or a lighting apparatus. The organic light-emitting device can also be used as exposure light sources of image-forming apparatuses and backlights of liquid crystal display apparatuses.

A display apparatus includes a display unit that includes the organic light-emitting device of this embodiment. The display unit has pixels and each pixel includes the organic light-emitting device of this embodiment. The display apparatus may be used as an image display apparatus of a personal computer, etc.

The display apparatus may be used in a display unit of an imaging apparatus such as digital cameras and digital video cameras. An imaging apparatus includes the display unit and an imaging unit having an imaging optical system for capturing images.

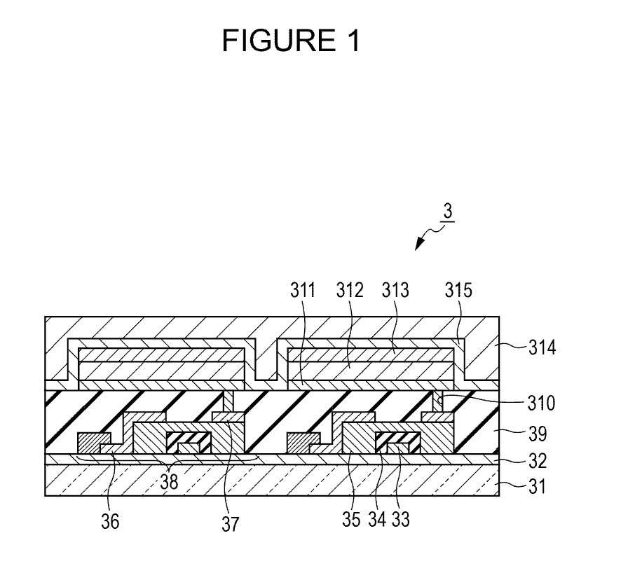

FIG. 1 is a schematic cross-sectional view of an image display apparatus having an organic light-emitting device in a pixel unit. In the drawing, two organic light-emitting devices and two thin film transistors (TFTs) are illustrated. One organic light-emitting device is connected to one TFT.

Referring to FIG. 1, in an image display apparatus 3, a moisture proof film 32 is disposed on a substrate 31 composed of glass or the like to protect components (TFT or organic layer) formed thereon. The moisture proof film 32 is composed of silicon oxide or a composite of silicon oxide and silicon nitride. A gate electrode 33 is provided on the moisture proof film 32. The gate electrode 33 is formed by depositing a metal such as Cr by sputtering.

A gate insulating film 34 covers the gate electrode 33. The gate insulating film 34 is obtained by forming a layer of silicon oxide or the like by a plasma chemical vapor deposition (CVD) method or a catalytic chemical vapor deposition (cat-CVD) method and patterning the film. A semiconductor layer 35 is formed over the gate insulating film 34 in each region that forms a TFT by patterning. The semiconductor layer 35 is obtained by forming a silicon film by a plasma CVD method or the like (optionally annealing at a temperature 290° C. or higher, for example) and patterning the resulting film according to the circuit layout.

A drain electrode 36 and a source electrode 37 are formed on each semiconductor layer 35. In sum, a TFT 38 includes a gate electrode 33, a gate insulating layer 34, a semiconductor layer 35, a drain electrode 36, and a source electrode 37. An insulating film 39 is formed over the TFT 38. A contact hole (through hole) 310 is formed in the insulating film 39 to connect between a metal anode 311 of the organic light-emitting device and the source electrode 37.

A single-layer or a multilayer organic layer 312 that includes an emission layer and a cathode 313 are stacked on the anode 311 in that order to constitute an organic light-emitting device that functions as a pixel. First and second protective layers 314 and 315 may be provided to prevent deterioration of the organic light-emitting device.

The switching device is not particularly limited and a metal-insulator-metal (MIM) element may be used instead of the TFT described above.

### EXAMPLES

### Example 1

### Synthesis of Example Compound 3

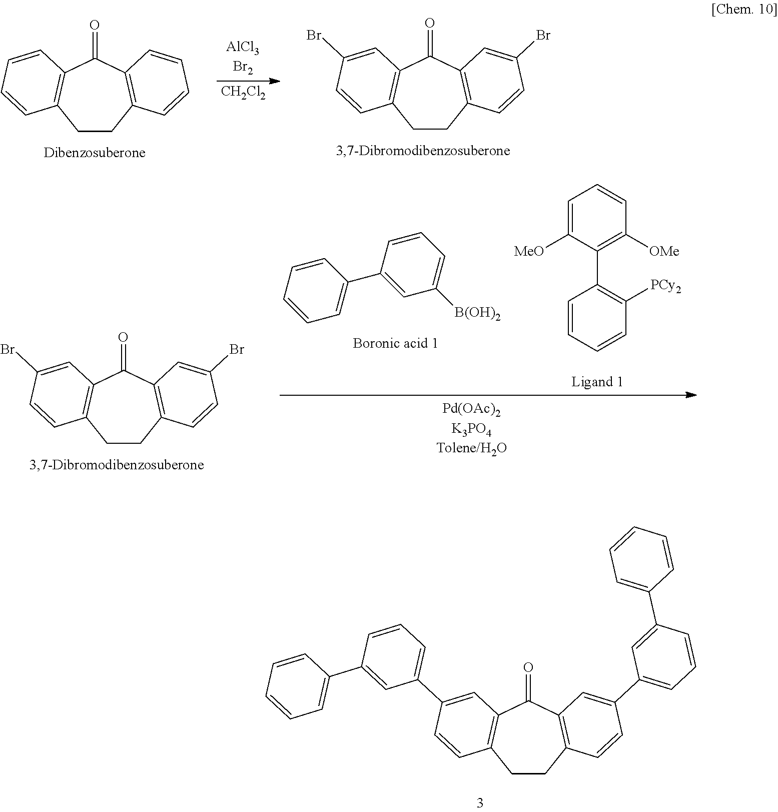

The following reagents and solvents were placed in a 200 mL round-bottomed flask.

### Dibenzosuberone: 8.7 g

### Dichloromethane: 100 ml

The mixture was cooled to 0° C., and 12.3 g of aluminum chloride and then 20 g of bromine were added to the mixture.

The reaction mixture was maintained at 0° C. and stirred for 4 hours. Upon completion of the reaction, ice water was added to the reaction solution, followed by stirring. The mixture was extracted with chloroform, and the chloroform layer was purified by flash chromatography. The resulting crude product was recrystallized twice with an ethyl acetate solvent. As a result, 3.2 g of 3,7-dibromodibenzosuberone crystals were obtained.

Next, the following reagents were placed in a 100 mL round-bottomed flask.

### 3,7-Dibromodibenzosuberone: 600 mg

Boronic acid 1: 700 mg
Palladium acetate: 30 mg

### Ligand 1: 108 mg

Potassium phosphate: 766 mg

### Toluene: 50 ml

### Water: 3 ml

The reaction solution was refluxed for 8 hours under heating and stirring in a nitrogen atmosphere. Upon completion of the reaction, the organic layer was separated, dried over magnesium sulfate, and filtered. The solvent in the filtrate was distilled away under reduced pressure, and the crude product was purified by flash chromatography (ethyl acetate:heptane=1:2). Obtained white powder was recrystallized twice with a toluene/ethanol solvent. After vacuum drying at 110° C., sublimation purification was conducted at about 10⁻⁴ Pa and 230° C. As a result, 434 mg of high-purity Example Compound 3 was obtained.

Matrix-assisted laser desorption ionization-time-of-flight mass spectroscopy (MALDI-TOF-MS) confirmed M⁺ of this compound, i.e., 512.467.

T₁ energy of Example Compound 3 was measured as follows.

A phosphorescence spectrum of a toluene diluted solution of Example Compound 3 was measured in an Ar atmosphere at 77 K and an excitation wavelength of 300 nm. The T₁ energy was calculated from the peak wavelength of the first emission peak of the obtained phosphorescence spectrum. The T₁ energy was 439 nm on a wavelength basis.

The LUMO level was measured by the following process.

A chloroform diluted solution of Example Compound 3 was formed into a thin film by spin coating and the HOMO level was measured with AC-3 (Riken Keiki Co., Ltd.). The HOMO level was −6.62 eV. The band gap was measured from the absorption edge with V-560 (JASCO Corporation). The band gap was 3.32 eV. The band gap was added to the HOMO level to calculate the LUMO level, which gave −3.30 eV.

Tg of Example Compound 3 measured with DSC-6200 (Seiko Instruments Inc.) was 65.2° C.

### Example 2

### Synthesis of Example Compound 22

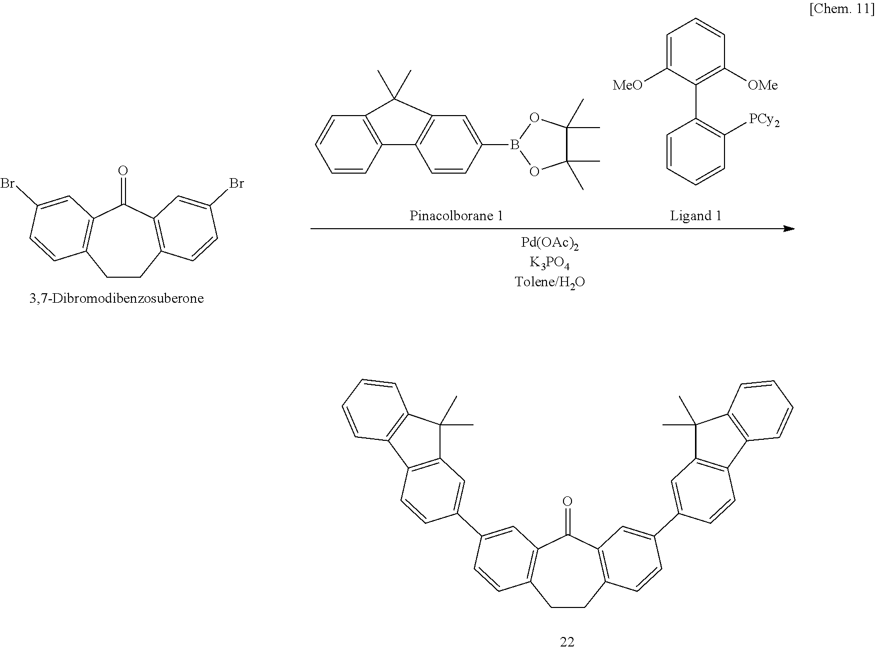

The following reagents and solvents were placed in a 200 mL round-bottomed flask.

### 3,7-Dibromodibenzosuberone: 700 mg

### Pinacolborane 1: 1290 mg

Palladium acetate: 17.5 mg

### Ligand 1: 63 mg

Potassium phosphate: 1620 mg

### Toluene: 50 mL

### Water: 3 mL

The reaction mixture was refluxed for 8 hours under heating and stirring at nitrogen atmosphere. Upon completion of the reaction, the organic layer was separated, dried over magnesium sulfate, and filtered. The solvent in the filtrate was distilled away under reduced pressure, and the crude product was purified by flash chromatography (toluene). The resulting white powder was dispersed and washed twice with an ethyl acetate solvent. After vacuum drying at 110° C., sublimation purification was conducted at about 10⁻⁴ Pa and 260° C. As a result, 396 mg of high-purity Example Compound 22 was obtained.

Matrix-assisted laser desorption ionization-time-of-flight mass spectroscopy (MALDI-TOF-MS) confirmed M⁺ of this compound, i.e., 592.317.

T₁ energy of Example Compound 22 was measured as follows.

A phosphorescence spectrum of a toluene diluted solution of Example Compound 22 was measured in an Ar atmosphere at 77 K and an excitation wavelength of 300 nm. The T₁ energy was calculated from the peak wavelength of the first emission peak of the obtained phosphorescence spectrum. The T₁ energy was 484 nm on a wavelength basis.

A chloroform diluted solution of Example Compound 22 was formed into a thin film by spin coating and the HOMO level was measured with AC-3 (Riken Keiki Co., Ltd.). The HOMO level was −6.21 eV. The band gap was measured from the absorption edge with V-560 (JASCO Corporation). The band gap was 3.12 eV. The band gap was added to the HOMO level to calculate the LUMO level, which gave −3.09 eV.

Tg of Example Compound 22 measured with DSC-6200 (Seiko Instruments Inc.) was 119.9° C.

### Comparative Example 1

Tg of dibenzosuberone was measured with DSC-6200 (Seiko Instruments Inc.) for comparison. Tg was −47.9° C.

The results show that the dibenzosuberone compound of the invention has high Tg.

### Example 3

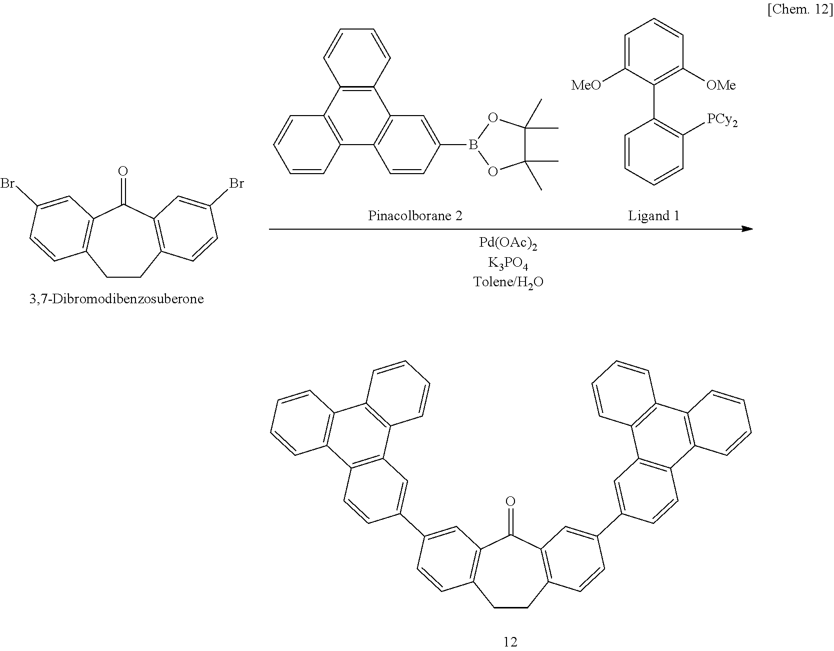

Example Compound 12 was obtained as in Example 2 except that pinacolborane 1 was changed to pinacolborane 2. M⁺ of this compound, 660.2 was confirmed by MALDI-TOF MS.

### Example 4

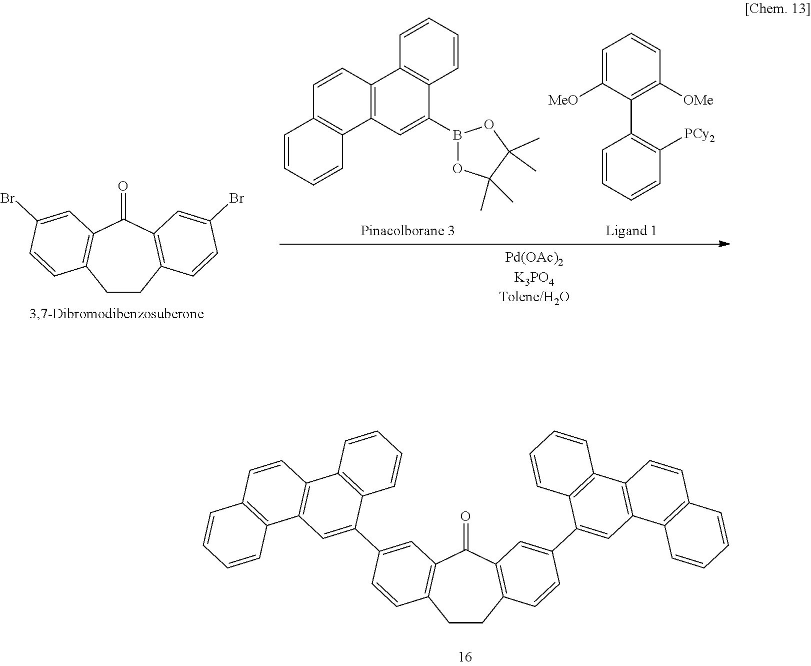

Example Compound 16 was obtained as in Example 2 except that pinacolborane 1 was changed to pinacolborane 3. M⁺ of this compound, 660.2 was confirmed by MALDI-TOF MS.

### Example 5

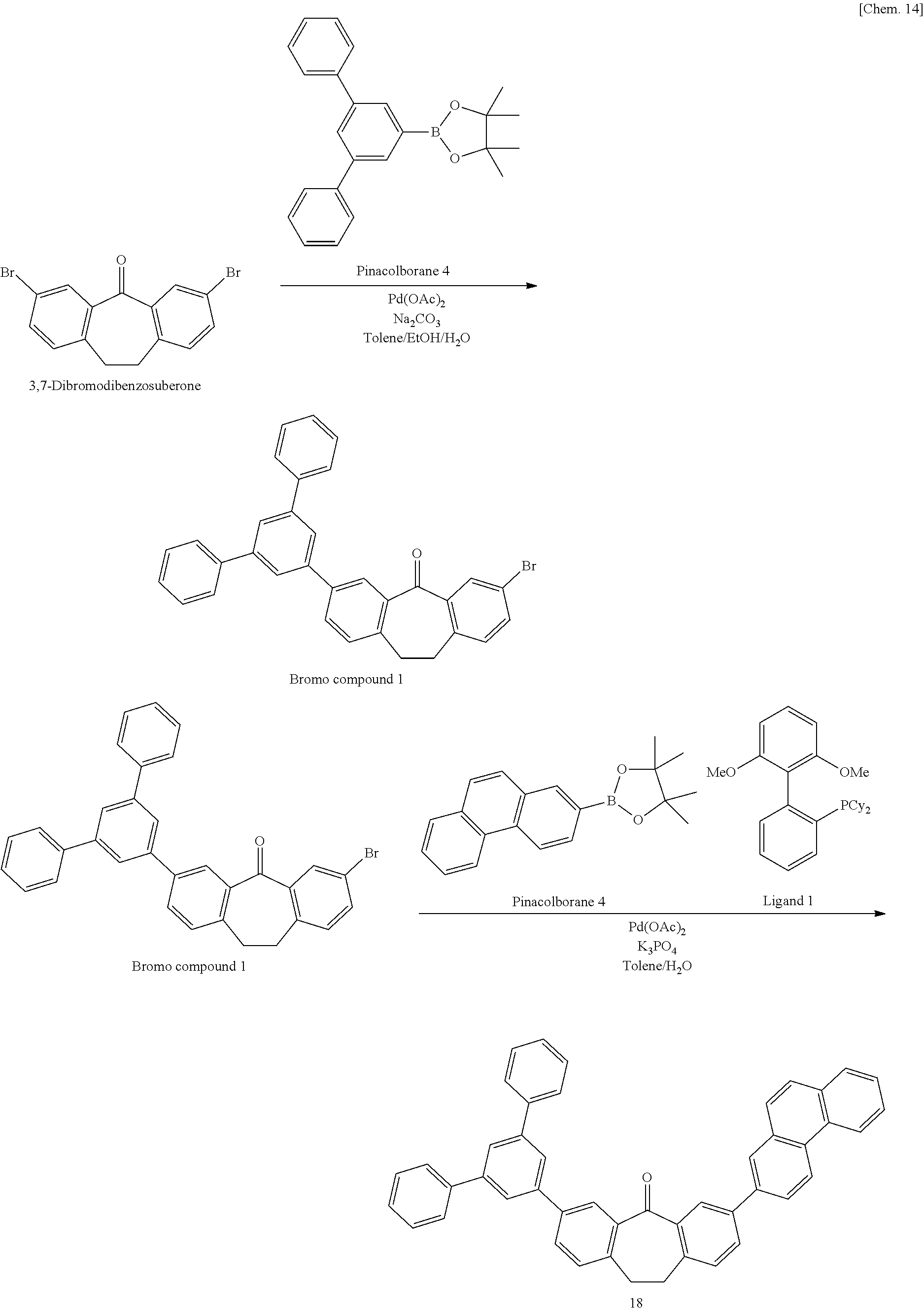

The following reagents and solvents were placed in a 200 mL round-bottomed flask.

### 3,7-Dibenzosuberone

### Pinacolborane 4

### Tetrakistriphenylphosphine

Sodium carbonate

### Toluene

### Ethanol

### Water

The reaction mixture was maintained at 80° C. and stirred for 4 hours. Upon completion of the reaction, water was added to the reaction mixture, followed by stirring. The reaction mixture was then extracted with toluene. The toluene layer was condensed and columned on silica gel. As a result, a bromo compound 1 was obtained.

Example Compound 18 was obtained as in Example 2 except that 3,7-dibromodibenzosuberone was changed to the bromo compound 1 and pinacolborane 1 was changed to pinacolborane 5.

M⁺ of this compound, 612.2 was confirmed by MALDI-TOF MS.

### Example 6

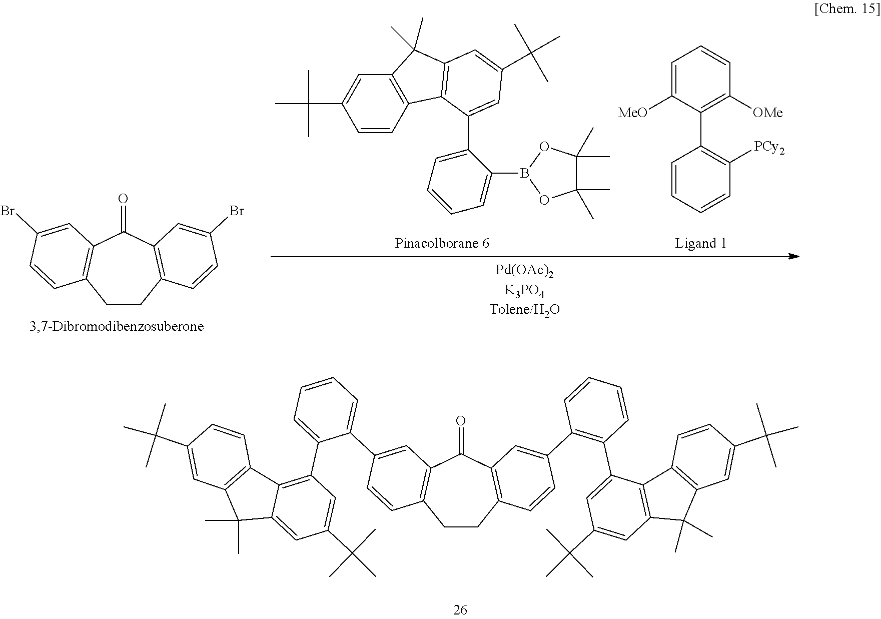

Example Compound 26 was obtained as in Example 2 except that pinacolborane 1 was changed to pinacolborane 6.

M⁺ of this compound, 968.5 was confirmed by MALDI-TOF MS.

### Example 7

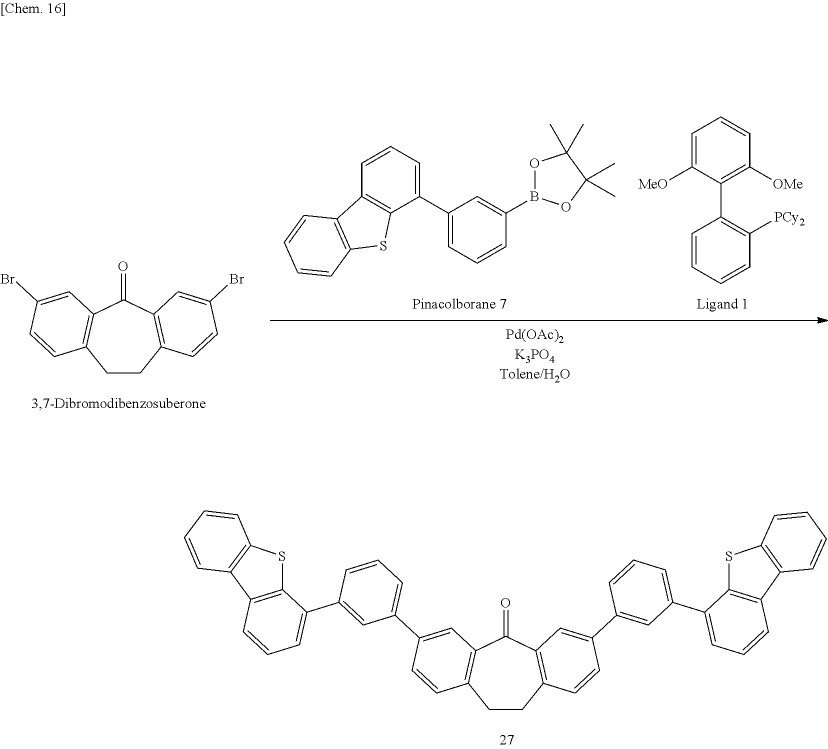

Example Compound 27 was obtained as in Example 2 except that pinacolborane 1 was changed to pinacolborane 7. M⁺ of this compound, 724.1 was confirmed by MALDI-TOF MS.

### Example 8

In this example, an organic light-emitting device having an anode/hole transport layer/emission layer/electron transport layer/cathode structure, these layers being sequentially formed on a substrate, was prepared by the following process.

Indium tin oxide (ITO) was sputter-deposited on a glass substrate to form a film 120 nm in thickness functioning as an anode. This substrate was used as a transparent conductive support substrate (ITO substrate). Organic compound layers and electrode layers below were continuously formed on the ITO substrate by vacuum vapor deposition under resistive heating in a 10⁻⁵ Pa vacuum chamber. The process was conducted so that the area of the opposing electrodes was 3 mm².

Hole transport layer (40 nm) HTL-1
Emission layer (30 nm)

Host material 1: I-1

Host material 2: none

Guest material: Ir-1 (10 wt %)

Electron transport layer 1 (10 nm) Example Compound 3
Electron transport layer 2 (30 nm) ETL-1
Electron transport layer 3 (0.5 nm) LiF

### Cathode (100 nm) Al

Of the host materials, one with a higher ratio is referred to as “host material 1” and the other is referred to as “host material 2”. The electron transport layer 1 is a layer in contact with the cathode-side of the emission layer, the electron transport layer 2 is a layer in contact with the cathode-side of the electron transport layer 1, and the electron transport layer 3 is a layer in contact with the cathode.

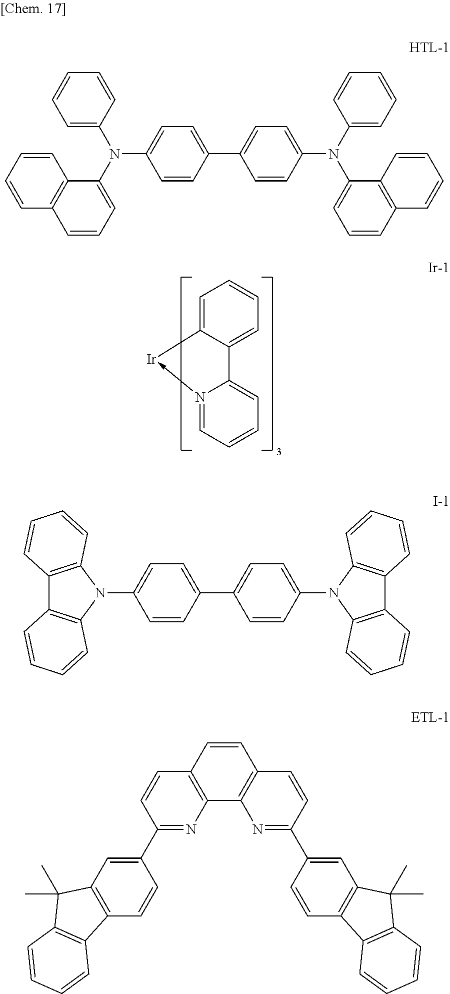

A protective glass plate was placed over the organic light-emitting device in dry air to prevent deterioration caused by adsorption of moisture and sealed with an acrylic resin adhesive. Thus, an organic light-emitting device was produced.

A voltage of 6.6 V was applied to the ITO electrode functioning as a positive electrode and an aluminum electrode functioning as a negative electrode of the resulting organic light-emitting device. The emission efficiency was 56 cd/A and emission of green light with a luminance of 4000 cd/m² was observed. The CIE color coordinate of the device was (x, y)=(0.30, 0.62).

### Examples 9 to 24

Devices were produced as in Example 8 except that the host material 1, the host material 2, the guest material, the electron transport layer 1 material, and the electron transport layer 2 material were changed. Each device was evaluated as in Example 8. The results are shown in Table 2.

TABLE 2

| | | | | Electron | Electron | Emission | | |
|---|---|---|---|---|---|---|---|---|
| | Host | Host | Guest | transport | transport | efficiency | Voltage | Emission |
| | material 1 | material 2 | material | material 1 | material 2 | (cd/A) | (V) | color |
| Ex. 9 | I-1 | Compound | Ir-1 | Compound 3 | ETL-1 | 53 | 6.6 | Green |
| | | 3 (10%) | | | | | | |
| Ex. 10 | I-4 | None | Ir-7 | Compound 3 | ETL-1 | 12 | 7.4 | Blue |
| | | | | | | | | green |
| Ex. 11 | I-5 | None | Ir-8 | Compound 3 | ETL-1 | 10 | 7.1 | Blue |
| Ex. 12 | I-1 | None | Ir-1 | Compound 12 | ETL-1 | 40 | 6.7 | Green |
| Ex. 13 | I-1 | Compound | Ir-1 | Compound 18 | ETL-1 | 47 | 6.1 | Green |
| | | 18 (10%) | | | | | | |
| Ex. 14 | I-1 | None | Ir-1 | Compound 18 | ETL-1 | 53 | 6.5 | Green |
| Ex. 15 | I-3 | None | Ir-3 | Compound 22 | ETL-1 | 49 | 6.6 | Green |
| Ex. 16 | I-3 | Compound | Ir-3 | Compound 22 | ETL-1 | 56 | 6.0 | Green |
| | | 22 (10%) | | | | | | |
| Ex. 17 | I-2 | None | Ir-4 | Compound 26 | ETL-1 | 55 | 6.9 | Green |
| Ex. 18 | I-2 | Compound | Ir-4 | Compound 26 | ETL-1 | 53 | 6.9 | Green |
| | | 26 (10%) | | | | | | |
| Ex. 19 | I-1 | Compound | Ir-1 | Compound 3 | ETL-1 | 54 | 6.6 | Green |
| | | 22 (10%) | | | | | | |
| Ex. 20 | I-1 | Compound | Ir-1 | Compound 22 | ETL-1 | 50 | 6.2 | Green |
| | | 3 (10%) | | | | | | |
| Ex. 21 | I-1 | Compound | Ir-1 | Compound 3 | None | 43 | 8.3 | Green |
| | | 3 (10%) | | | | | | |
| Ex. 22 | I-1 | None | Ir-1 | Compound 3 | None | 47 | 8.6 | Green |
| Ex. 23 | I-3 | Compound | Ir-3 | None | ETL-1 | 41 | 6.1 | Green |
| | | 3 (10%) | | | | | | |
| Ex. 24 | I-3 | Compound | Ir-3 | None | ETL-1 | 40 | 6.2 | Green |
| | | 22 (10%) | | | | | | |

Ex.: Example

The results show that when the dibenzosuberone compound is used as an electron transport material or an emission layer material of a phosphorescent organic light-emitting device, high emission efficiency can be achieved.

As described above, the dibenzosuberone compound of the invention is a compound having high T₁ energy and a deep LUMO level. When the dibenzosuberone compound is used in an organic light-emitting device, high emission efficiency and stability can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-159625, filed Jul. 14, 2010, which is hereby incorporated by reference herein in its entirety.

1. An organic light-emitting device material represented by general formula (1): 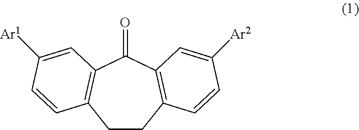
where Ar¹ and Ar² each independently denote a substituent selected from a phenyl group, a biphenyl group, a terphenyl group, a naphthyl group, a phenanthrenyl group, a fluorenyl group, a triphenylenyl group, and a chrysenyl group, and may each independently include at least one of an alkyl group, an aromatic hydrocarbon group, and an aromatic heterocyclic group.

2. An organic light-emitting device comprising:
a pair of electrodes which are an anode and a cathode; and
an organic compound layer disposed between the pair of electrodes,
wherein the organic compound layer contains the organic light-emitting device material according to claim 1.

3. The organic light-emitting device according to claim 2, wherein the organic compound layer is an emission layer.

4. The organic light-emitting device according to claim 2, further comprising:
an additional organic compound layer,
wherein the additional organic compound layer is in contact with a cathode-side of the emission layer.

5. The organic light-emitting device according to claim 4,
wherein the additional organic compound layer contains the organic light-emitting device material.

6. The organic light-emitting device according to claim 3, wherein the emission layer contains a host material and a guest material, the host material includes two or more materials, and one of the two or more materials is the organic light-emitting device material.

7. The organic light-emitting device according to claim 6, wherein the guest material is a phosphorescent material.

8. The organic light-emitting device according to claim 7, wherein the phosphorescent material is an iridium complex.

9. An image display apparatus comprising:
the organic light-emitting device according to claim 2; and
a switching device connected to the organic light-emitting device.

10. A lighting apparatus comprising a substrate and the organic light-emitting device according to claim 2.
